(19) United States
(12) Patent Application Publication
(10) Pub. No.: US 2017/0331069 A1
(43) Pub. Date: Nov. 16, 2017

(54) Nano-Film Transfer and Visibly Transparent Organic and Perovskite Solar Cells and LEDs with a Nano-Film Layer

(71) Applicant: Massachusetts Institute of Technology, Cambridge, MA (US)

(72) Inventors: Yi Song, Cambridge, MA (US); Jin-Yong Hong, Malden, MA (US); Jing Kong, Winchester, MA (US)

(73) Assignee: Massachusetts Institute of Technology, Cambridge, MA (US)

(21) Appl. No.: 15/593,677

(22) Filed: May 12, 2017

Related U.S. Application Data
(60) Provisional application No. 62/335,786, filed on May 13, 2016.

(51) Int. Cl. H01L 51/52; H01L 51/44; H01L 51/00; H01L 51/56

(52) U.S. Cl. CPC H01L 51/5203; H01L 51/56; H01L 51/0021; H01L 51/0097; H01L 51/442

(57) ABSTRACT

A transfer stamp comprising a nano-film layer is formed on a substantially transparent polymeric substrate, wherein the substantially transparent polymeric substrate comprises an indirect adhesion layer adhered to the nano-film. The nano-film layer of the transfer stamp is applied to a surface of a target substrate; the nano-film layer is positioned between the indirect adhesion layer and the target substrate.

### RELATED APPLICATION

This application claims the benefit of U.S. Provisional Application No. 62/335,786, filed 13 May 2016, the entire content of which is incorporated herein by reference.

### BACKGROUND

As the world's energy demand increases and as the “internet of things” progresses, ideas such as ubiquitous energy harvesting and solar-collecting windows may become reality.

The use of electronics has become increasingly pervasive over the past several decades and will likely continue expanding in the future. Because it is not always practical to connect electronic devices to the power grid due to size, location, or mobility constraints, researchers often envision powering such devices using cheap, visually un-obstructive solar cells.

### SUMMARY

A method for nano-film transfer and devices, such as organic solar cell, light-emitting diodes, and perovskite solar cells, that can be produced therefrom are described herein, where various embodiments of the apparatus and methods may include some or all of the elements, features and steps described below.

In a method for nano-film transfer, a transfer stamp comprising a nano-film layer is formed on a substantially transparent polymeric substrate, wherein the substantially transparent polymeric substrate comprises an indirect adhesion layer adhered to the nano-film. The nano-film layer of the transfer stamp is applied to a surface of a target substrate; the nano-film layer is positioned between the indirect adhesion layer and the target substrate.

An organic solar cell or light-emitting diode comprises a nano-film electrode having a first side and a second side; a substantially transparent polymeric substrate contacting the first side of the nano-film electrode; and a substantially transparent target substrate contacting the second side of the nano-film electrode.

### BRIEF DESCRIPTION OF THE DRAWINGS

FIG. 1 is a schematic illustration of a nano-film transfer method.

FIG. 2 illustrates a device structure with approximate layer thicknesses.

FIG. 3 shows the energy levels for the different layers of FIG. 2.

FIG. 4 plots the absorption spectra of PDTP-DFBT, PC₆₀BM, and PC₇₀BM spin-coated onto glass.

FIG. 5 is a photograph taken through a PC₆₀BM device. Dotted lines outline the corners of the device.

FIG. 6 plots cumulative absorption spectra of a PDTP:PC₆₀BM device as each layer is added from the bottom (cathode) to the top (anode). Shaded regions indicate absorption contribution of each layer within the visible regime. Percentages in the legend refer to the total visible absorption of the layer. The cross pattern underneath the MoO₃ spectrum (purple) indicates wavelengths where absorption decreases as a result of the MoO₃ film.

FIG. 7 includes images and drawings a-f. Optical image a is of graphene dry-transferred onto MoO₃ using a PMMA/PDMS stamp; full adhesion is only achieved after heating to 150° C. Photograph b shows graphene dry-transferred onto MoO₃ film without the EVA adhesion layer; red arrows indicate regions with poor adhesion. Adhesion is achieved only after heating to 150° C. Schematic illustration c shows a stamp used for the dry transfer of a graphene top electrode. Photograph d shows a PDMS stamp with graphene; the top and bottom edges of the region with graphene are indicated with dotted lines. Photograph e and optical image f show graphene dry-transferred onto MoO₃ using a EVA/PMMA/PDMS stamp; absence of optical interference patterns and air bubbles indicate that full adhesion is achieved at room temperature.

FIG. 8 is an illustration of different device configurations.

FIG. 9 plots the J-V curves of all device configurations for PC₇₀BM devices on glass substrates.

FIG. 10 provides a comparison between Gr PC₆₀BM and PC₇₀BM devices on glass.

FIG. 11 plots J-V curves of Gr/Gr devices when illuminated from the glass (cathode) side versus the PDMS (anode) side. The J-V curve of an ITO/Gr device illuminated from glass/ITO side is included as a reference. The lower-right bar chart shows the average J_{SC} values for these configurations.

FIG. 12 provides a comparison of PC₆₀BM and PC₇₀BM Gr/Gr devices on rigid glass substrates and on flexible PEN substrates.

FIG. 13 plots J-V curves of devices on paper and Kapton tape.

FIG. 14 plots J-V curves showing the degradation of a Gr/Al device as it is bent to smaller radii of curvature.

FIG. 15 includes plots of device performances when the device is bent to different radii of curvature

FIG. 16 is a plot of the absorption spectrum of PDTP:PC₆₀BM and PDTP:PC₇₀BM devices and transmittance at 550 nm.

FIG. 17 is a plot of the external quantum efficiency (EQE) spectrum for reference devices with ITO/Al electrodes on glass.

FIG. 18 is a plot of the performance of DBP/C60 planar heterojunction devices.

FIG. 19 is a plot of the performance of P3HT:PCBM bulk heterojunction devices.

FIG. 20 is an illustration of the structure of a quantum-dot solar cell with a graphene top electrode and a process for depositing the graphene top electrode using a nano-film transfer method.

FIG. 21 is a schematic illustration of a method for doping graphene using nitric acid.

FIG. 22 is an illustration of the structure of a perovskite solar cell with a graphene top electrode and a process for depositing the graphene top electrode using the nano-film transfer method.

In the accompanying drawings, like reference characters refer to the same or similar parts throughout the different views; and apostrophes are used to differentiate multiple instances of the same or similar items sharing the same reference numeral. The drawings are not necessarily to scale; instead, an emphasis is placed upon illustrating particular principles in the exemplifications discussed below.

### DETAILED DESCRIPTION

The foregoing and other features and advantages of various aspects of the invention(s) will be apparent from the following, more-particular description of various concepts and specific embodiments within the broader bounds of the invention(s). Various aspects of the subject matter introduced above and discussed in greater detail below may be implemented in any of numerous ways, as the subject matter is not limited to any particular manner of implementation. Examples of specific implementations and applications are provided primarily for illustrative purposes.

Unless otherwise herein defined, used or characterized, terms that are used herein (including technical and scientific terms) are to be interpreted as having a meaning that is consistent with their accepted meaning in the context of the relevant art and are not to be interpreted in an idealized or overly formal sense unless expressly so defined herein. For example, if a particular composition is referenced, the composition may be substantially (though not perfectly) pure, as practical and imperfect realities may apply; e.g., the potential presence of at least trace impurities (e.g., at less than 1 or 2%) can be understood as being within the scope of the description. Likewise, if a particular shape is referenced, the shape is intended to include imperfect variations from ideal shapes, e.g., due to manufacturing tolerances. Percentages or concentrations expressed herein can be in terms of weight or volume. Processes, procedures and phenomena described below can occur at ambient pressure (e.g., about 50-120 kPa—for example, about 90-110 kPa) and temperature (e.g., −20 to 50° C.—for example, about 10-35° C.) unless otherwise specified.

Although the terms, first, second, third, etc., may be used herein to describe various elements, these elements are not to be limited by these terms. These terms are simply used to distinguish one element from another. Thus, a first element, discussed below, could be termed a second element without departing from the teachings of the exemplary embodiments.

Spatially relative terms, such as “above,” “below,” “left,” “right,” “in front,” “behind,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

Further still, in this disclosure, when an element is referred to as being “on,” “connected to,” “coupled to,” “in contact with,” etc., another element, it may be directly on, connected to, coupled to, or in contact with the other element or intervening elements may be present unless otherwise specified.

The terminology used herein is for the purpose of describing particular embodiments and is not intended to be limiting of exemplary embodiments. As used herein, singular forms, such as “a” and “an,” are intended to include the plural forms as well, unless the context indicates otherwise. Additionally, the terms, “includes,” “including,” “comprises” and “comprising,” specify the presence of the stated elements or steps but do not preclude the presence or addition of one or more other elements or steps.

Additionally, the various components identified herein can be provided in an assembled and finished form; or some or all of the components can be packaged together and marketed as a kit with instructions (e.g., in written, video or audio form) for assembly and/or modification by a customer to produce a finished product.

Over the past decade, graphene has attracted significant attention due to its remarkable physical and chemical characteristics. From an optoelectronics standpoint, graphene is both electrically conductive and optically transparent—a combination of properties rarely found together—making it an advantageous composition for transparent conductors in photovoltaic devices. Chemical vapor deposition (CVD) allows for the synthesis of graphene films of arbitrary dimensions suitable for large-area devices. Many types of devices including solar cells, light emitting diodes (LEDs), photodetectors, and lasers using CVD-grown graphene electrodes have already been demonstrated. Within the sub-category of solar cells, graphene has been applied to a number of technologies, such as crystalline silicon dye-sensitized, quantum dot, organic CdTe, GaAs, and perovskite. For transparent devices, we focus on organic photovoltaic cells (OPVs) because a wide selection of organic donor and acceptor compounds with different absorption spectra are available, allowing for optimized transmittance across the visible regime. Furthermore, OPVs typically require a small amount of active material, which offers the opportunity for realizing low cost, flexible devices when combined with appropriate substrates and electrodes.

Currently, most laboratory OPVs consist of organic layers and electron/hole transport layers with a combined thickness of 100 nm sandwiched between a ˜150 nm thick indium tin oxide (ITO) anode and a ˜100 nm thick metal cathode. Both the sputtering of ITO and evaporation of metal contacts are slow processes that require high vacuum. Thus, aside from being opaque due to the metal top electrode, such devices are inefficient from a cost and materials usage standpoint because the electrodes require more material than the active layer. Fabricating semi-transparent OPVs presents further challenges because both electrodes need to be transparent. In past reports, ITO is typically chosen as the bottom electrode, while possible materials for the transparent top electrode include metal nanowires, conductive polymers, thin metal layers, and graphene. In particular, graphene complements the cost advantages of OPVs because it is less than 1 nm thick and can be synthesized from virtually any carbon source. Here, the versatility of graphene is demonstrated by using it as both the anode and cathode in a single device. The highly transparent electrodes are combined with organic compounds that absorb primarily in the UV and NIR regimes to achieve devices with up to 4% power conversion efficiency (PCE) and optical transmittance as high as 62% across the visible spectrum. Furthermore, these devices can be fabricated on a variety of flexible substrates, including plastic and paper. Devices with graphene electrodes are more resilient to bending than those with ITO electrodes.

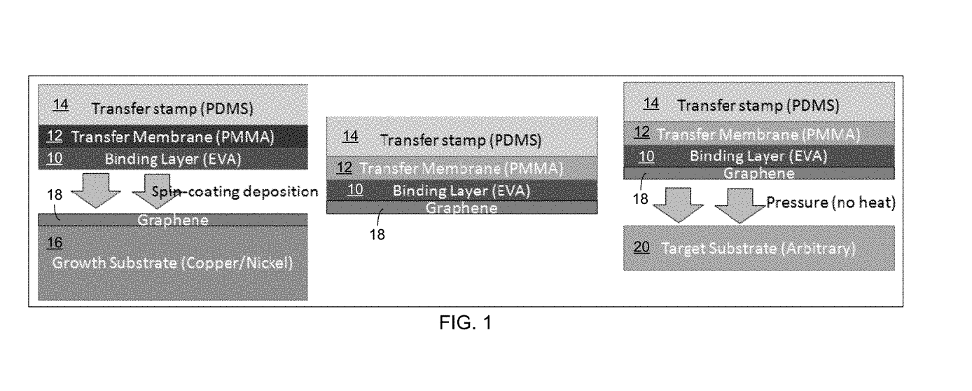

Because graphene is typically synthesized on metallic substrates, the film must be transferred onto other substrates to be used for various applications. The transfer process often involves heating the substrates or immersing the substrate in water or organic solvents and can therefore limit the scope of possible applications. A novel method for transferring graphene and other nano-films, which can be used, e.g., to fabricate the transparent electrode in an organic solar cell or an organic light-emitting diode is schematically illustrated in FIG. 1. In a first step, a binding layer 10, transfer membrane 12, and transfer stamp 14 are deposited onto the growth substrate 16 with graphene 18. Second, the growth substrate is removed by chemical etching. Third, the remaining stack (including the stamp 14, membrane 12, binding layer 10, and graphene 18) is pressed onto the target substrate 20.

While in previous approaches, the binding layer 10 has been deposited on the target substrate 20, the binding layer 10 here is deposited onto the graphene 18; and the graphene 18, after transfer, is in direct contact with the target substrate 20—rather than having the binding layer 10 sandwiched between the graphene 18 and the target substrate 20, as in previous approaches. Thus, the binding layer 10 used in this fashion will henceforth be referred to as an “indirect adhesion layer.” Unlike previous “dry-transfer” methods, this process, through the use of the indirect adhesion layer, allows nano-films to be transferred without heating the substrate. Additionally, in the present approach, the laminate structure can be left intact and can serve as an encapsulation layer for the graphene 18 and target substrate 20. Thus, a potential application for this method is transferring graphene 18 as the transparent electrode for organic solar cells or organic light-emitting diodes.

When used in a solar cell, the transparent electrode (e.g., graphene 18) allows light to enter the active layers of the device, where the light is converted to electrical current, and collects the resultant electric current. When used in a light-emitting diode, the transparent electrode (e.g., graphene 18) directs electric current into the active layers of the target substrate 20, where the electric current is converted to light, and allows the light to exit the device.

In the exemplification below, transparent organic solar cells with graphene 18 as both the anode and cathode are fabricated on flexible substrates 20, such plastic and paper. The graphene anode was deposited at room temperature via the nano-film transfer technique described here using ethylene-vinyl-acetate as the indirect adhesion layer.

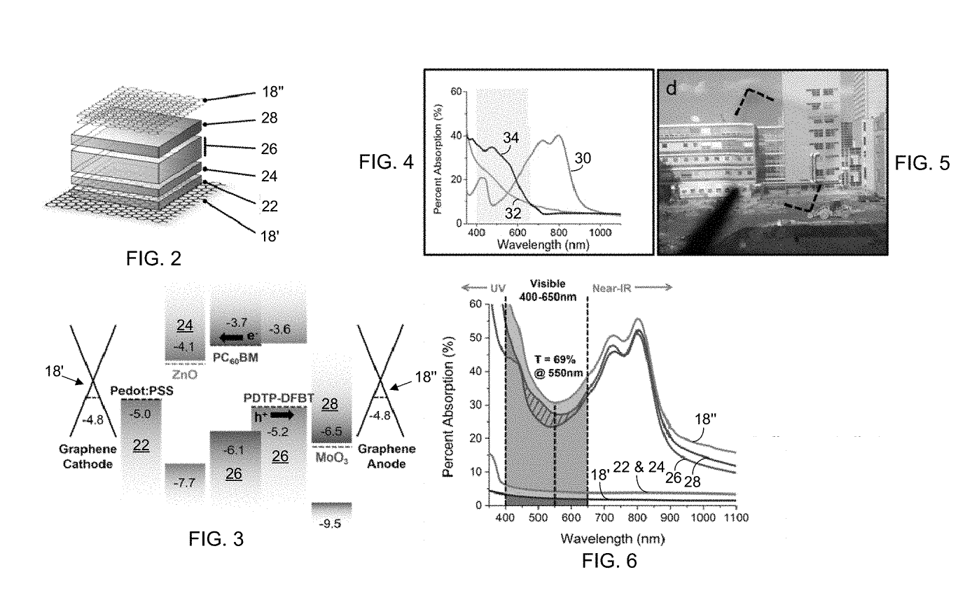

The structure of the solar cell device, including the following layers: 1L Gr(ITO) cathode 18′ (˜1 nm thick)/Pedot:PSS polymer interlayer 22 (20 nm thick)/ZnO electron transport layer 24 (25 nm thick)/PDTP-DFBT:PCBM active layer 26 (100 nm thick)/MoO₃ hole transport layer 28 (20 nm thick)/2L Gr(Al) anode 18″ (˜1 nm thick), is shown in FIG. 2; and the corresponding energy levels are shown in FIG. 3. Devices with a graphene anode 18″ and cathode 18′ (henceforth referred to as Gr/Gr devices) can be ˜180-nm thick in total, compared to 400-nm thickness conventional devices with ITO and Al electrodes (ITO/Al devices). For this discussion, the cathode 18′ (graphene or ITO) deposited onto the substrate 20 is referred to as the “bottom” electrode; and the anode 18″ deposited on top of the organic layers (graphene or Al) is referred to as the “top” electrode. Rigid control devices were fabricated on borosilicate glass, whereas flexible devices were fabricated on polyethylene naphthalate (PEN), paper, and polyimide tape.

The bulk heterojunction blend serving as the active layer 26 was composed of poly[2,7-(5,5-bis-(3,7-dimethyl octyl)-5H-dithieno[3,2-b:20,30-d]pyran)-alt-4,7-(5,6-difluoro-2,1,3-benzothiadiazole)] (PDTP-DFBT) as the donor and [6,6]-phenyl-C61-butyric acid methyl ester (PC₆₀BM) or [6,6]-phenyl-C71-butyric acid methyl ester (PC₇₀BM) as the acceptor. PDTP-DFBT 30 (hereafter written as PDTP for brevity) is a low-bandgap polymer that absorbs primarily from 600-900 nm, while PC₆₀BM 32 and PC₇₀BM 34 absorb in a shorter wavelength range, as shown in FIG. 4. PC₆₀BM 32 is less absorptive than PC₇₀BM 34, so using a PDTP:PC₆₀BM blend results in higher optical transmittance but lower power conversion efficiency (PCE).

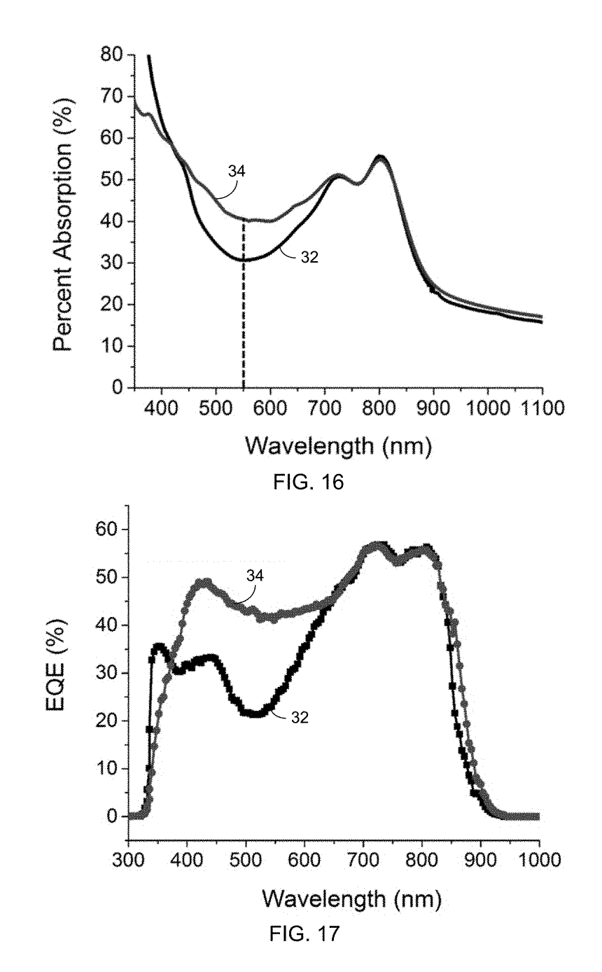

In both cases, the mixed bulk heterojunction layer was highly transparent in the visible regime (400-650 nm) (as seen in the photograph of FIG. 5). Although transparent, the PC₆₀BM devices appeared green, whereas the PC₇₀BM devices were brown. FIG. 6 shows the light absorption of each layer [i.e., the top electrode 18″ (2L graphene, ˜5% absorption), the hole transport layer 28 (MoO₃, ˜3% absorption), the active layer 26 (PDTP-DFBT:PC_{60/70}BM, ˜31%/˜38% absorption), the electron transport layer 24 and polymer interlayer 22 (Zn and Pedot:PSS, ˜3% absorption), and the bottom electrode 18′ (1L graphene, ˜3% absorption)] in the device across the visible spectrum in a PC₆₀BM device. PDTP:PC₆₀BM films absorbed 31% of incoming visible light, which accounts for the majority of the optical losses. The single-layer graphene cathode 18′, the PEDOT:PSS interlayer 22, and the ZnO electron transport layer 24 only reduced the overall transmittance by 6%. Surprisingly, depositing the MoO₃ hole transport layer 28 (HTL) onto the PDTP:PCBM film 26 appeared to slightly enhance the optical transmittance, even though stand-alone MoO₃ films deposited on glass or PEN reduces the overall transmittance. Similar phenomena have been observed in the past for organic solar cells. The two-layer (2L) graphene anode 18″ absorbs an additional 5% of the light, which is consistent with 2.3% absorption from each layer of graphene and significantly better than ITO or alternatives, such as silver nanowire films. Overall, the optical transmittance of the PC₆₀BM 32 and PC₇₀BM 34 devices was measured to be ˜69% for PC₆₀BM 32 and ˜59% for PC₇₀BM 34 at 550 nm and ˜61% for PC₆₀BM 32 and ˜54% for PC₇₀BM 34 integrated across the visible spectrum, as shown in FIG. 16—values that are among the highest for transparent solar cells with comparable PCE's in literature thus far.

To assemble the bottom electrode (cathode), monolayer (1L) graphene 18′ was transferred onto the substrate 20 using the standard Poly(methyl methacrylate) (PMMA) transfer method reported in literature (e.g., in U.S. Pat. No. 8,535,553 B2). The PMMA transfer membrane 12 was removed by immersing in acetone followed by thermal annealing for glass substrates and immersing in heated acetone for flexible substrates. As shown in the past, removing PMMA residue promotes good device yield and high performance. Monolayer graphene is used because a single transfer limits the amount of polymer residue and preserves the transparency of the substrate. Depositing the ZnO electron transport layer (ETL) 24 directly onto graphene via the sol-gel method severely degrades the sheet resistance of the graphene film, as discussed infra. Thus, a PEDOT:PSS interlayer 22 was first deposited, which p-dopes graphene films, to enhance its conductivity and to provide protection during the subsequent deposition of ZnO. Aqueous PEDOT:PSS cannot be spun-cast directly onto graphene due to graphene's hydrophobicity, but mixing the solution with alcohol (in this case, tert-Butanol) improves its wettability. After depositing PEDOT:PSS and ZnO, the sheet resistance was measured to be 450 Ω/sq on glass and 550 Ω/sq on PEN (detailed discussion can be found in the supporting information, infra). Even though PEDOT:PSS is a high-work-function hole transport layer (HTL), while ZnO is a low-work-function electron transport layer (ETL), the two materials make an ohmic contact and, therefore, do not add a significant series resistance to the device.

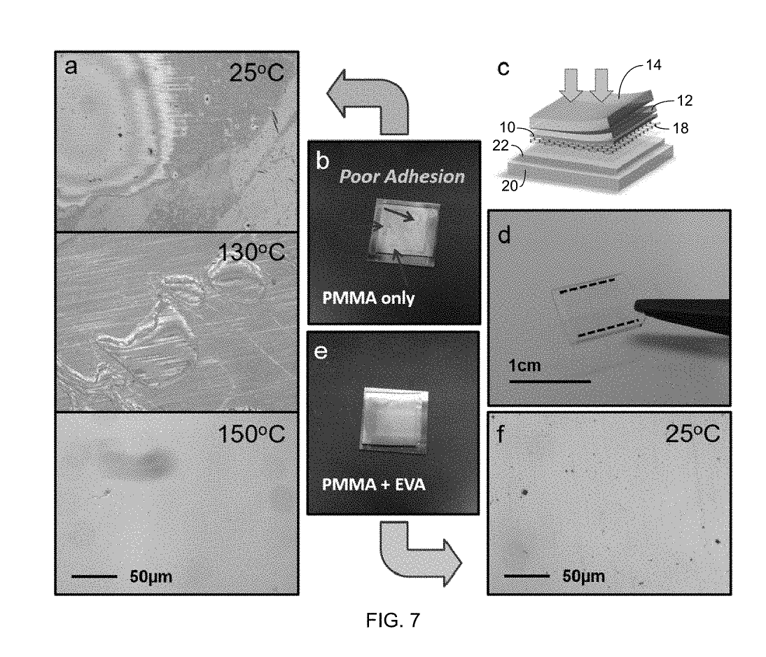

Using graphene as the top electrode 18″ involves transferring graphene onto the device after the active layer 26 and interlayers 24 and 28 (ETL, HTL) have already been deposited. Because PDTP:PCBM is sensitive to moisture and because the MoO₃ HTL dissolves in water, the standard PMMA transfer process is not suitable for depositing the graphene top electrode 18″. A common dry-transfer procedure involves coating the graphene with PMMA and attaching the membrane to a polydimethylsiloxane (PDMS) stamp, allowing the stack to be removed from water and pressed onto the target substrate. However, the target substrate must be heated to ensure proper adhesion; when MoO₃ is chosen as the target substrate, it must be heated to 150° C. before the PMMA/graphene film adheres (as shown in image a of FIG. 7).

To overcome this challenge, the aforementioned transfer method was applied using ethylene-vinyl-acetate (EVA) as the indirect adhesion layer 10 between the graphene 18 and PMMA transfer membrane 12 (images b and c of FIG. 7). EVA is soft and flexible at room temperature, which makes it an advantageous membrane for the dry transfer of graphene, while the PMMA is more rigid. Even though the EVA binding layer 10 is not in direct contact with the target substrate 20 (MoO₃ in this case), its mechanical properties allows graphene 18 to conform to the surface. As shown in image d of FIG. 7, the EVA layer 10 allows the graphene 18 to adhere to the MoO₃ substrate 20 without heating. The PDMS transfer stamp 14 does not affect the optical properties of the device and was, therefore, usually left on, though the PDMS transfer stamp 14 can optionally be removed by heating the stack to 80° C. and gently peeling. In one embodiment, the PDMS layer 14 is 0.5 mm thick; the PMMA layer 12 is 300 nm thick; and the EVA layer 10 is 100 nm thick.

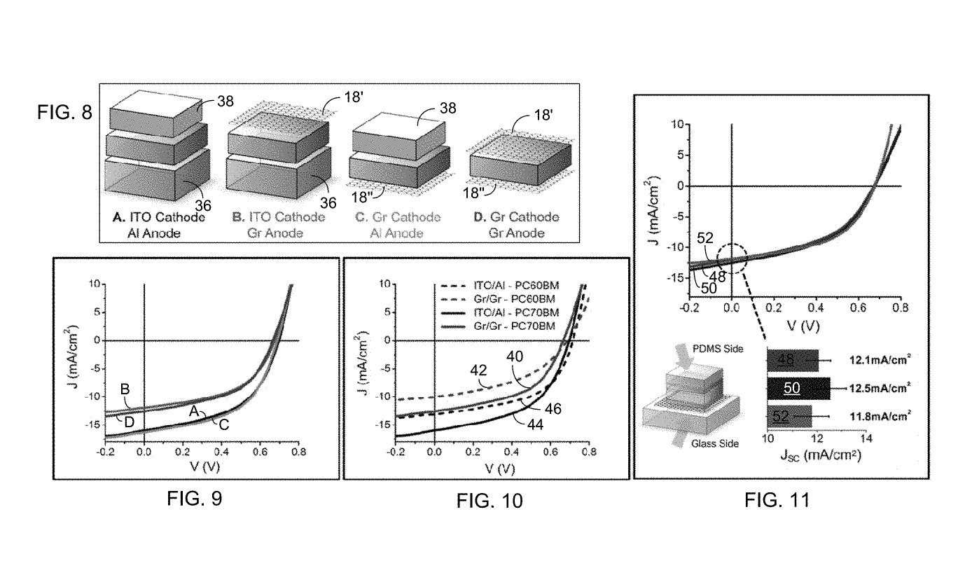

Four different device configurations, as shown in FIG. 8, were compared to evaluate the role of graphene as a cathode (C), anode (B), or a combination of both (D), with an ITO cathode used in embodiments A and B and an aluminum anode used in embodiments A and C. For each electrode configuration, devices with PC₇₀BM and PC₆₀BM as the acceptor (active layer 26) were compared. The electric current density versus voltage (J-V) curves of each configuration of PC₇₀BM devices on glass, which represents the highest achieved PCE values, are shown in FIG. 9. The difference in PCE between ITO/Al (A) and Gr/Al (C) devices is minimal. Gr/Al devices have slightly higher J_{SC} due to better optical transmittance of graphene compared to ITO, but lower fill factor, owing to graphene's higher sheet resistance.

The PCE for these two electrode configurations is ˜5.8% for PC₇₀BM devices and ˜4.7% for PC₆₀BM devices, which is comparable to previously reported values for polymer and hybrid solar cells with graphene bottom electrodes.

The EQE spectra for devices made with PC₆₀BM 32 and PC₇₀BM 34 are shown in FIG. 17; the theoretical J_{SC} values calculated from the EQE spectra are consistent with the actual measured J_{SC}. Transparent devices (ITO/Gr and Gr/Gr) have lower J_{SC} than opaque devices because they do not have a reflective anode. Thus, the best PCE achieved for Gr/Gr devices on glass is 4.1% for PC₇₀BM devices 40 and 3.0% for PC₆₀BM devices 42, as shown in FIG. 10, where results for ITO/Al devices with PC₇₀BM 44 and PC₆₀BM 46 are plotted for comparison. Transparent ITO/Gr and

Gr/Gr devices can be illuminated from either the top (through the PDMS, graphene and MoO₃) or the bottom (through the substrate, PEDOT:PSS, and ZnO). We find that illuminating from the top (PDMS side) produces marginally more J_{SC} than from the bottom (glass side), which can be attributed to the better transmittance of the graphene anode stack and MoO₃ compared to the glass substrate, PEDOT:PSS interlayer, and ZnO ETL (as seen in FIG. 11, which plots the electric current density, J, as a function of voltage, V, for Gr/Gr on a glass slide 48, Gr/Gr on a PDMS slide 50, and ITO/Gr on a glass slide 52).

A full summary of device performance parameters can be found in Table I, below. PDTP-DFBT and PCBM are chosen as the donor and acceptor because they offer high optical transmittance. However, this graphene transfer process is universal and is, therefore, applicable to any other active material. Some examples of less transparent devices made using the same procedure are identified, infra.

TABLE 1

| | J_{SC} (mA/cm²) | | | PCE (%) bottom/ |
|---|---|---|---|---|
| Device | bottom/top | V_{OC} (V) | Fill Factor | top |
| PC60BM on Glass | | | | |
| ITO/Al | 13.1 | 0.71 | 0.52 | 4.8 ± 0.07 |
| ITO/Gr | 9.8 | 0.69 | 0.48 | 3.2 ± 0.13 |
| Gr/Al | 12.8 | 0.71 | 0.52 | 4.7 ± 0.11 |
| Gr/Gr | 9.7/10.0 | 0.68 | 0.46 | 3.0 ± 0.16/3.1 ± 0.16 |
| PC60BM on PEN/Paper | | | | |
| ITO/Al | 12.3 | 0.70 | 0.53 | 4.5 ± 0.15 |
| ITO/Gr | 9.7 | 0.68 | 0.49 | 3.1 ± 0.12 |
| Gr/Al | 12.5 | 0.71 | 0.46 | 4.1 ± 0.15 |
| Gr/Gr | 9.2/9.8 | 0.68 | 0.43 | 2.6 ± 0.12/2.8 ± 0.13 |
| PC70BM on Glass | | | | |
| ITO/Al | 15.9 | 0.69 | 0.54 | 5.9 ± 0.06 |
| ITO/Gr | 11.8/12.6 | 0.67 | 0.53 | 4.2 ± 0.09/4.5 ± 0.10 |
| Gr/Al | 16.3 | 0.69 | 0.52 | 5.8 ± 0.12 |
| Gr/Gr | 12.1/12.5 | 0.67 | 0.49 | 4.0 ± 0.13/4.1 ± 0.14 |
| PC70BM on PEN | | | | |
| ITO/Al | 15.0 | 0.69 | 0.53 | 5.5 ± 0.18 |
| Gr/Gr | 11.5/12.4 | 0.67 | 0.45 | 3.5 ± 0.14/3.7 ± 0.16 |

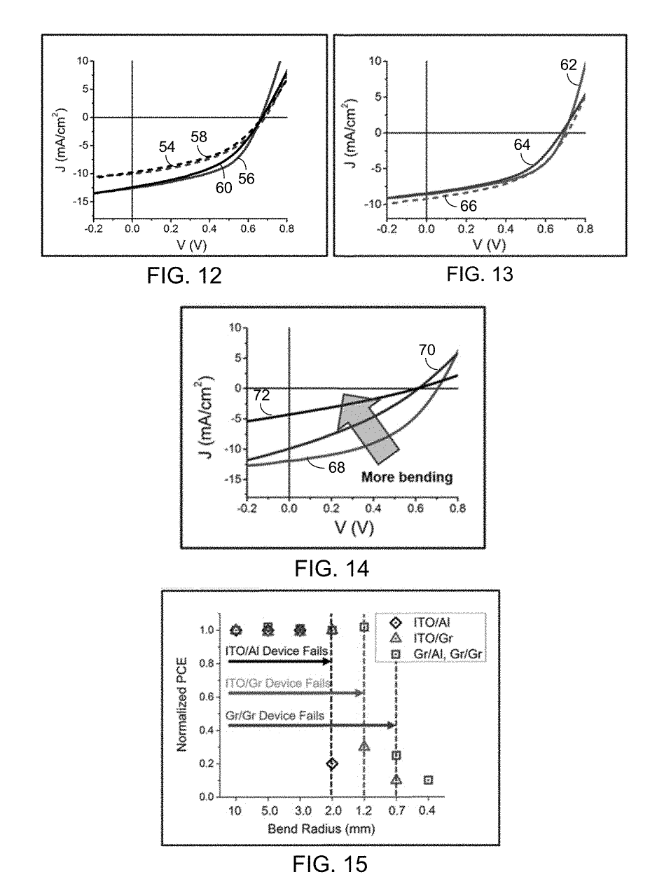

Flexible devices were fabricated using transparent plastic polyethylene naphthalate (PEN) as the substrate. The sheet resistance of graphene transferred onto PEN is higher than on glass, resulting in greater series resistance. Furthermore, the rougher surface of PEN introduces the potential for more shorting pathways. Both of these effects serve to reduce the fill factor of the final devices. Also, because PEN has a higher cut-off wavelength than glass, I_{SC} is slightly lower when illuminated from the bottom. FIG. 12 shows a comparison of PC₆₀BM 58 and PC₇₀BM 60 devices fabricated on PEN versus PC₆₀BM 54 and PC₇₀BM 56 devices fabricated on glass. Because the graphene top electrode is transparent, the device can be illuminated from the top, allowing us to choose non-transparent substrates. Thus, devices are also demonstrated on opaque paper and translucent KAPTON tape (from E. I. du Pont de Nemours and Company, Wilmington, Del., USA), which are relevant to applications such as paper electronics and peel-and-stick solar cells. We successfully fabricated ITO/Gr 62 and Gr/Gr 64 devices on paper and ITO/Gr 66 devices on KAPTON tape; device performances were roughly equal for all substrates (FIG. 13). Even after device fabrication, text printed on the paper could still be read. In all cases, as summarized in Table I, the PCE of flexible devices is slightly lower than that of rigid devices due to a combination of the aforementioned factors.

Potential applications for these devices include powering wearable devices using peel-and-stick solar cells or extremely low-cost paper electronics. For such applications, the devices will inevitably be bent or folded, which makes mechanical robustness an important consideration. To evaluate the flexibility of these devices, the devices were incrementally bent to decreasing radii of curvature, and the resulting J-V curves were measured. In all cases, the J-V characteristics remain largely unchanged until the device is bent past a critical radius, which varies depending on whether the electrodes are graphene, ITO, or aluminum.

Past the critical radius, J_{SC}, V_{OC}, and fill factor all decrease as the electrodes lose conductivity from mechanical damage and short through the active layers, as shown in FIG. 14, which features plots of current density as a function of voltage for bending with the following radii of curvature: 1.2 mm 68, 0.7 mm 70, and 0.4 mm 72. Although flexible devices have been demonstrated with both graphene and metal oxide bottom electrodes, the herein-described devices with graphene electrodes are shown to have superior mechanical robustness. As shown in FIG. 15, ITO/Al devices fail at a radius of curvature of about 2 mm. Examining the film under an optical microscope reveals that the ITO is cracked after bending; thus, it is likely that the brittle ITO layer limits the device's flexibility. Gr/Al and Gr/Gr devices are more robust; they can be bent to radii of less than 1 mm (which requires folding the PEN so that is becomes permanently deformed) before failing. All devices, including those with ITO, can be bent repeatedly (>100 cycles), provided that the bending radius is ˜20% larger than the critical radius.

In summary, the above-described newly developed universal nano-film transfer method using an indirect adhesion layer is applied to fabricate flexible, transparent organic photovoltaic cells (OPVs) using graphene as both the anode and cathode. These devices can have optical transmittances of greater than 60% across the visible spectrum, making them some of the most transparent solar cells in literature. Furthermore, graphene-based devices on flexible substrates are extremely robust and can withstanding significant bending without degradations in performance. Finally, because this cold-transfer process places no significant requirements on the underlying substrate, the same process is suitable for a variety of organic or inorganic optoelectronic devices, such as organic light-emitting diodes (LEDs) and perovskite solar cells, and can serve as a framework for further developing such technologies in the near future.

### Methods

### Graphene Synthesis and Transfer

Single-layer graphene was synthesized on copper foil via low-pressure chemical vapor deposition (LPCVD). Prior to growth, the copper foil (Alfa Aesar, 25 um) was cleaned by sonicating in nickel etchant (Transene, type TFB) for 90 seconds and rinsing in de-ionized (DI) water. The single-layer graphene (SLG) cathode was transferred using the standard PMMA transfer process reported in literature. The PMMA was removed by immersing in acetone followed by thermal annealing for glass substrates and immersing in acetone at 80° C. for flexible substrates. Before graphene transfer, paper substrates are coated with a layer of hard-baked SU-8 photoresist, and Kapton© tape is peeled from the backing layer and stuck onto glass.

### Device Fabrication

Graphene cathodes were prepared by patterning the transferred SLG using photolithography. PEDOT:PSS (Clevios AI 4083) was mixed with tert-butanol (Alfa Aesar) in a 3:1 volume ratio and spin-coated at 4000 rpm onto the graphene. ITO cathodes were prepared by sputtering 150 nm of ITO onto the substrate through a shadow mask. The ZnO ETL was deposited onto the graphene or ITO cathodes by dissolving zinc acetate dihydrate in methanol (0.3M) and spin-coating onto the device, followed by baking in dry air at 200° C. for 10 minutes. PDTP-DFBT (1-material) was dissolved in 1,2-dichlorobenzene and filtered through a 0.45 um PFTE syringe filter. PC₆₀BM (Sigma Aldrich) and PC₇₀BM (1-material) were also dissolved in 1,2-dichlorobenzene (Sigma Aldrich). The solutions were mixed in a 1:2 donor-to-acceptor ratio and spin-coated for 120 seconds at 900 revolutions per minute (rpm) in a nitrogen glovebox, producing a ˜100 nm-thick film. After drying, 20 nm of MoO₃ was deposited via thermal evaporation. For devices with Al anodes, 100 nm of Al was thermally evaporated through a shadow mask.

### Graphene Top Electrode

EVA (Sigma Aldrich, 45% vinyl acetate) was dissolved (at 5% weight) in xylene and spin-coated at 2500 rpm onto graphene grown on copper foil. PMMA was spin-coated onto the EVA to provide mechanical rigidity to the film. The copper was dissolved in copper etchant (Transene, CE-100) and the floating graphene/EVA/PMMA film was scooped onto a second piece of copper with graphene, producing a two-layer graphene film. The copper/2LG/EVA/PMMA was cut into small pieces and attached to the PDMS transfer stamps before the copper was again etched away. Finally, the stamps were gently pressed onto the fabricated devices at room temperature. For flexibility tests, the PDMS stamp was removed by heating the stack to 80° C. for 5 minutes and gently peeling.

### Measurements

The sheet resistance of the graphene films was measured using a four-point probe station. Absorption spectra was measured using a Cary 5000 UV-Visisble-NIR spectrophotometer. I/V curves were measured in a nitrogen glovebox under AM1.5 illumination calibrated using a Newport 91150 V reference cell. Device areas for graphene-based electrodes were nominally 1.4 mm²; exact areas were measured under an optical microscope. Larger reference devices (ITO/Al) with nominal area of 5.4 mm² were also fabricated and measured through a metal aperture. There was no discernable difference in performance between larger and smaller reference devices. External quantum efficiency (EQE) measurements on references devices were performed using chopped monochromatic light from a xenon lamp (Thermo Oriel 66921) through an optical fiber without bias illumination. To perform flexibility tests, devices were bent to various radii of curvature by wrapping them around metal rods and flattened again before measuring I/V characteristics.

### Supporting Information:

### Sheet Resistance of Graphene Films

In our lab, the typical sheet resistance for continuous monolayer graphene transferred onto SiO₂ is about 300 Ω/sq at 1.4×10′³ cm⁻² carrier concentration. Films transferred onto plastic substrates, such as PEN, have slightly higher sheet resistance due to lower doping levels. The following table shows the sheet resistances of graphene monolayers measured at various points in the device fabrication procedure.

TABLE 2

| Step | Glass | | PEN | |
|---|---|---|---|---|
| After Transfer, no annealing | 450-600 | Ω/sq | 500-800 | Ω/sq |
| Leave in air 48 h | 400 | Ω/sq | 400 | Ω/sq |
| After thermal annealing | 300 | Ω/sq | — | |
| After ZnO deposition | ~1500-2500 | Ω/sq | ~1500-2500 | Ω/sq |
| (no PEDOT:PSS) | | | | |
| After Pedot:PSS deposition | 250 | Ω/sq | 300 | Ω/sq |
| PEDOT:PSS + ZnO | 450 | Ω/sq | 550 | Ω/sq |
| (Methanol) | | | | |
| PEDOT:PSS + ZnO | ~2000 | Ω/sq | ~2000 | Ω/sq |
| (Methoxyethanol) | | | | |

Depositing ZnO onto graphene via the sol-gel method appears to drastically decrease doping levels and increase the sheet resistance. Typical carrier concentration after ZnO deposition is less than 10′² cm⁻²—less than 10% of typical values before the procedure. Spin-coating PEDOT:PSS (with tert-Butanol) reduces the sheet resistance slightly, but more importantly, keeps the value at reasonable levels even after ZnO deposition.

Devices with Other Active Layers:

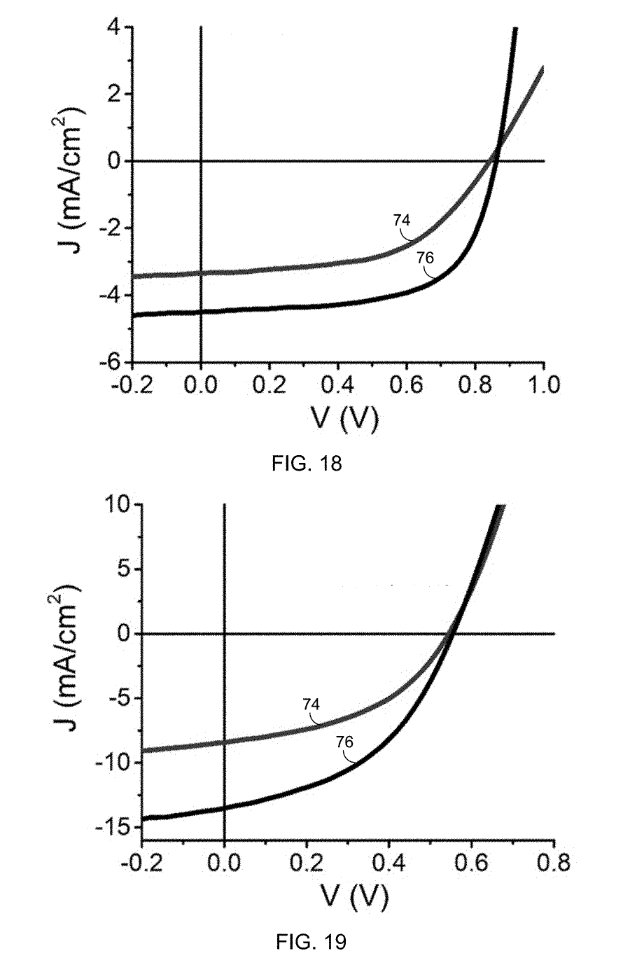

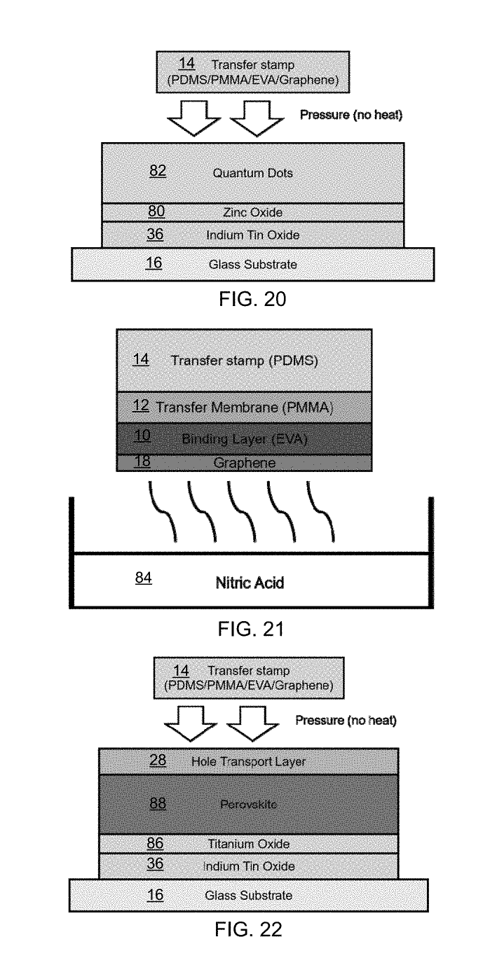

The performance of Gr/Gr (1.5%) devices made with other active materials (DBP/PC₆₀BM) compared to ITO/Al (2.3%) reference devices is shown in the plot of FIG. 18. In all cases, J_{SC} is reduced because the device is transparent, and the fill factor is reduced because of the higher resistance of the graphene. The PCE is indicated in the plot legends. The structure of this small molecule planar heterojunction device is as follows: ITO (Gr)/ZnO (20 nm)/C60 (40 nm)/DBP (25 nm)/MoO₃ (20 nm)/Al (Gr).

The performance of Gr/Gr (1.9%) and ITO/Al (3.4%) in a P3HT:PCBM bulk heterojunction device with the following structure is plotted in FIG. 19: ITO (or Gr)/ZnO (20 nm)/P3HT:PC₇₀BM (100 nm)/MoO₃ (20 nm)/Al (or Gr).

### Fabricating Quantum-Dot Solar Cells Using a Nano-Film Transfer Method:

Indium tin oxide (ITO) 78 is deposited onto a glass substrate 16 by sputtering. The nominal thickness of the ITO electrode layer 36 is 150 nm. Zinc oxide 80 is deposited onto the ITO layer 36 by dissolving zinc acetate dihydrate and ethanolamine in 2-methoxyethanol at a concentration of 0.3 M and spin-coating onto the device, followed by baking in dry air at 200° C. for 10 minutes. The quantum-dot layer 82 is deposited onto zinc oxide 80 by sequential spin-coating steps. Lead sulfide solution is spun coated onto the substrate; a ligand exchange is performed by spin coating a solution of 1,2-ethanedithiol (EDT) or tetrabutylammonium iodide (TBAI); and the substrate is rinsed in methanol. This process is repeated 15 times to obtain a nominal film thickness of 250 nm. The PDMS/PMMA/EVA/graphene nano-film transfer stamp 14 is fabricated using the same method previously discussed.

As shown in FIG. 21, the graphene 18 is chemically doped by holding the nano-film transfer stamp 14 over nitric acid 84 with the graphene 18 side facing the nitric acid 14. Nitric acid vapor is deposited onto the graphene 18, improving its electrical conductivity. The nano-film transfer stamp 14 is then gently pressed onto the hole transport layer 28 of the solar cell.

### Fabricating Perovskite Solar Cells Using a Nano-Film Transfer Method:

In this embodiment, indium tin oxide (ITO) 36 is again deposited onto a glass substrate 16 by sputtering. Titanium oxide 86 is deposited onto the ITO 36 by spin coating a solution of titanium isopropoxide and annealing in air at 400° C. for 2 hours. A perovskite precursor solution is made by mixing lead acetate trihydrate and methylammonium iodide in a 1:3 molar ratio at a concentration of 0.88 M and dissolving in dimethylformamide. The perovskite precursor solution is spun coated onto the titanium oxide layer 86 at 2000 rpm and baked in dry air at 85° C. for 15 min, forming a dark brown perovksite film 88. A hole-transport-layer solution is made by dissolving 80 mg of Spiro-OMeTAD, 28.5 uL of 4-tertbutylpyridine, and 17.5 ml of lithium-bis(trifluoromethanesulfonyl)imide (Li-TFSI) solution in 1 mL of chlorobenzene. The hole-transport-layer solution is spun coated onto the perovskite layer 88 at 5000 rpm, forming a hole transport layer 28. The PDMS/PMMA/EVA/graphene nano-film transfer stamp 14 is fabricated using the same method previously discussed. The nano-film transfer stamp 14 is then gently pressed onto the hole transport layer 28.

In describing embodiments of the invention, specific terminology is used for the sake of clarity. For the purpose of description, specific terms are intended to at least include technical and functional equivalents that operate in a similar manner to accomplish a similar result. Additionally, in some instances where a particular embodiment of the invention includes a plurality of system elements or method steps, those elements or steps may be replaced with a single element or step. Likewise, a single element or step may be replaced with a plurality of elements or steps that serve the same purpose. Further, where parameters for various properties or other values are specified herein for embodiments of the invention, those parameters or values can be adjusted up or down by 1/100^{th}, 1/50^{th}, 1/20^{th}, 1/10^{th}, ⅕^{th}, ⅓^{rd}, ½, ⅔^{rd}, ¾^{th}, ⅘^{th}, 9/10^{th}, 19/20^{th}, 49/50^{th}, 99/100^{th}, etc. (or up by a factor of 1, 2, 3, 4, 5, 6, 8, 10, 20, 50, 100, etc.), or by rounded-off approximations thereof, unless otherwise specified. Moreover, while this invention has been shown and described with references to particular embodiments thereof, those skilled in the art will understand that various substitutions and alterations in form and details may be made therein without departing from the scope of the invention. Further still, other aspects, functions, and advantages are also within the scope of the invention; and all embodiments of the invention need not necessarily achieve all of the advantages or possess all of the characteristics described above. Additionally, steps, elements and features discussed herein in connection with one embodiment can likewise be used in conjunction with other embodiments. The contents of references, including reference texts, journal articles, patents, patent applications, etc., cited throughout the text are hereby incorporated by reference in their entirety; and appropriate components, steps, and characterizations from these references may or may not be included in embodiments of this invention. Still further, the components and steps identified in the Background section are integral to this disclosure and can be used in conjunction with or substituted for components and steps described elsewhere in the disclosure within the scope of the invention. In method claims (or where methods are elsewhere recited), where stages are recited in a particular order—with or without sequenced prefacing characters added for ease of reference—the stages are not to be interpreted as being temporally limited to the order in which they are recited unless otherwise specified or implied by the terms and phrasing.

What is claimed is:

1. A method for nano-film transfer, the method comprising:
forming a transfer stamp comprising a nano-film layer on a substantially transparent polymeric substrate, wherein the substantially transparent polymeric substrate comprises an indirect adhesion layer adhered to the nano-film; and
applying the nano-film layer of the transfer stamp to a surface of a target substrate, wherein the nano-film layer is between the indirect adhesion layer and the target substrate.

2. The method of claim 1, wherein the target substrate is a device selected from an organic, perovskite, or quantum-dot solar cell and a light-emitting diode.

3. The method of claim 1, wherein the nano-film layer comprises a composition selected from graphene, molybdenum disulfide, and hexagonal boron nitride.

4. The method of claim 3, wherein the indirect adhesion layer comprises ethylene-vinyl acetate (EVA).

5. The method of claim 4, wherein the transfer stamp further comprises:
a polydimethylsiloxane (PDMS) layer; and
a poly(methyl methacrylate) (PMMA) layer between the polydimethylsiloxane (PDMS) layer and the indirect adhesion layer.

6. The method of claim 3, wherein the target substrate comprises MoO₃, Spiro-OMeTAD, or PbS quantum dots.

7. The method of claim 3, wherein the transfer stamp is applied to the target substrate without immersing the target substrate in liquid.

8. The method of claim 3, wherein the transfer stamp is applied to the target substrate at a temperature in the range from 20 to 25° C.

9. The method of claim 3, wherein the surface of the target substrate to which the transfer stamp is applied is tortuous, and wherein the indirect adhesion layer and the nano-film conform to the tortuous surface of the target substrate.

10. The method of claim 3, wherein both the target substrate and the transfer stamp are flexible.

11. The method of claim 3, wherein the indirect adhesion layer adheres to the target substrate via Van der Waal forces extending through the nano-film between the indirect adhesion layer and the target substrate.

12. The method of claim 3, further comprising:
depositing the nano-film layer on a growth substrate; and
transferring the nano-film layer from the growth substrate to the substantially transparent polymeric substrate to form the transfer stamp.

13. The method of claim 12, further comprising chemically doping the nano-film layer with nitric acid to enhance electrical conductivity of the nano-film layer.

14. A device selected from an organic, perovskite, or quantum dot solar cell and a light-emitting diode, comprising:
a first nano-film electrode; and
a substantially transparent polymeric substrate contacting the first nano-film electrode.

15. The device of claim 14, wherein the device is a quatum-dot or perovskite solar cell.

16. The device of claim 14, further comprising:
a second nano-film electrode; and
a target substrate contacting the second nano-film electrode.

17. The device of claim 14, wherein the target substrate comprises a composition selected from polyethylene naphthalate, paper, and polyimide.

18. The device of claim 14, wherein the target substrate is substantially transparent.

19. The device of claim 18, wherein the substantially transparent polymeric substrate comprises:
a polydimethylsiloxane (PDMS) layer;
an ethylene-vinyl acetate (EVA) in contact with the nano-film electrode; and
a poly(methyl methacrylate) (PMMA) layer between the polydimethylsiloxane (PDMS) layer and the ethylene-vinyl acetate (EVA) layer.

20. The device of claim 19, wherein the device is flexible.
